(19) United States
(12) Patent Application Publication
(10) Pub. No.: US 2022/0052642 A1
(43) Pub. Date: Feb. 17, 2022

(54) SYNCHRONOUS MODULATION SYSTEM USING AMPLITUDE MODULATION

(71) Applicants: Marissa DÍAZ PIER, Atizapan de Zarazoga (MX); Herman DÍAZ ARIAS, Atizapan de Zarazoga (MX)

(72) Inventors: Marissa DÍAZ PIER, Atizapan de Zarazoga (MX); Herman DÍAZ ARIAS, Atizapan de Zarazoga (MX)

(21) Appl. No.: 17/274,910

(22) PCT Filed: Sep. 12, 2019
(86) PCT No.: PCT/MX2019/000098

§ 371 Date: Mar. 10, 2021

(30) Foreign Application Priority Data
Sep. 12, 2018 (MX) MX/A/2018/011028

(51) Int. Cl. H03C 1/46; H04L 27/04; H04L 27/06

(52) U.S. Cl. CPC H03C 1/46; H04L 27/06; H04L 27/04

(57) ABSTRACT

The invention relates to a synchronous modulation system using amplitude modulation, which basically consists of a modulator and a demodulator able to transmit digital signals at double the frequency of its carrier wave. For this purpose, the system uses analog and digital circuits that combine to modulate, separately, the positive half and the negative half of the carrier sine wave, such that in a single cycle of the carrier wave, two different information bits can be sent. The demodulator-modulator unit can be easily combined with other units to form wired or wireless communication systems and even optical or sonic systems with minimal generation of parasitic harmonics, resulting in a minimum bandwidth requirement for operation.

### FIELD OF THE INVENTION

This invention is developed mainly in the fields of Electronic Engineering and Telecommunications Engineering, since it is an equipment that allows the transmission of information and signals through various media, using a carrier wave and an original modulation system.

### BACKGROUND OF THE INVENTION

Throughout the 20th century and so far in the 21st century, various methods and systems have been developed to send information from one point to another over long distances, generally using wired or wireless means, however, the need to make multiple simultaneous transmissions avoiding that the information of each of the transmissions gets mixed with or corrupted by the interaction with other signals, has led to the use of a base signal or carrier frequency that allows a first and basic differentiation between several signals traveling on the same medium the most basic and traditional are amplitude modulation (AM) and frequency modulation (FM), which have been followed by systems such as FSK, PPM, OOK, and others.

There is a fundamental law in communications theory that states that the frequency of the carrier or carrier signal must be at least twice the maximum frequency of the information signal or modulating signal; this establishes a theoretical barrier to the design of telecommunication systems and limits the amount of information per second or the system rate. To send more information in a certain frequency band, even combinations of amplitude modulation with frequency modulation have been used, however, this type of signal processing produces secondary harmonics that widen the required bandwidth.

All traditional systems, such as those mentioned above, abide by the limiting two-to-one law mentioned above, obeying this basic law of telecommunications; our system proposes a modulation and demodulation alternative, which we have proven to bypass this fundamental law, making possible the transmission of much higher frequency signals using carriers of even half the frequency of the information.

### BRIEF DESCRIPTION OF THE INVENTION

The system proposed by our design consists of a modulator and a demodulator that work based on an amplitude modulation but sending different information in the positive and negative part of the sine wave used as a carrier, by performing this type of modulation, our system can send information at a frequency“2f”, using a carrier with frequency “f”, at first glance, this is incompatible with the fundamental law of telecommunications that states that the carrier frequency must be at least twice the maximum modulation frequency, nonetheless, in this case, we are managing to transmit information four times faster than the rate established by the theory.

The system is especially useful for sending digital information serially using an AM band, and the transport medium can be either wired or wireless, likewise, this design avoids the generation of excessive harmonics, allowing its operation within a limited bandwidth, contrary to what usually happens with other systems such as the OOK, which generates numerous harmonics, and its apparent transmission is a signal with a very broad spectrum. The modulation and demodulation in our system allow a wide margin of safety against noise and the ease of identifying synchronization points.

The essential elements of our system are the modulator and demodulator, which can be connected to other traditional elements of telecommunication systems such as amplifiers, power units and antennas or interfaces for cable transmission, to integrate a complete bidirectional telecommunication system.

### DESCRIPTION OF THE FIGURES

FIG. 1 shows a typical carrier signal and a typical modulating signal.

FIG. 2 shows a signal modulated by means of the system and the information it carries.

FIG. 3 shows the modulator circuit.

FIG. 4 shows a diagram of the telecommunication receiver.

FIG. 5 shows the demodulator circuit.

FIG. 6 shows a complete communication system, including the modulator and the demodulator.

FIG. 7 shows the diagram of the zero-centered circuit.

### DETAILED DESCRIPTION OF THE INVENTION

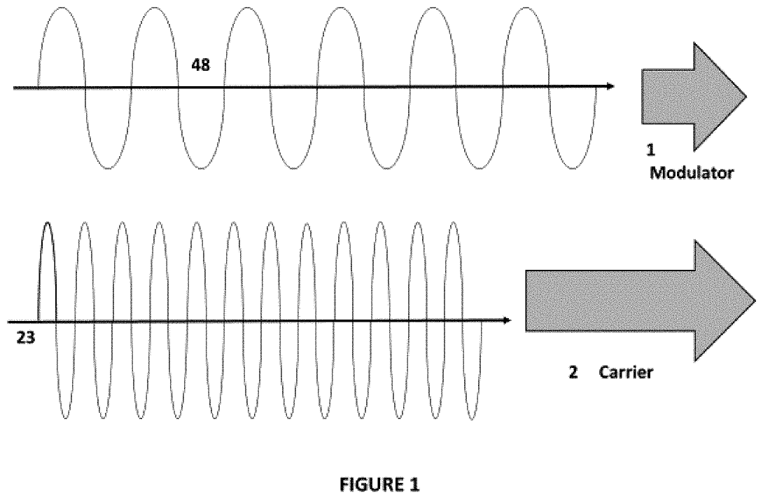

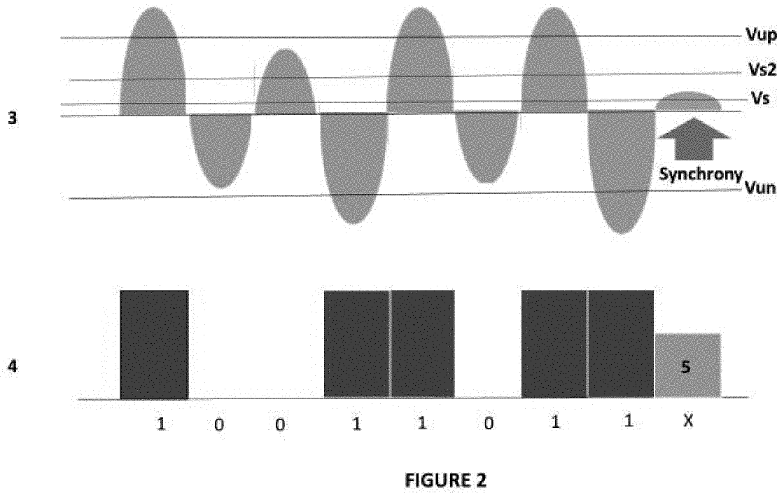

The synchronous modulation system using amplitude modulation object of the present invention is distinguished from other systems by the fact that it can handle transmitted signal frequencies equal to twice the carrier frequency; the system uses a modulator formed by a microcontroller in charge of controlling a set of attenuators that can be programmed to generate a certain degree of attenuation to both the positive and the negative part of a signal used as carrier and, as a counterpart, it has a demodulator that can accurately detect the attenuation levels imposed on each half cycle of oscillation of the carrier signal, this modulator and demodulator assembly forms the basis of this design and allows the transmission of serial digital signals at higher speeds than the carrier itself, the hybrid nature of this design lies in the combined use of analog and digital electronics within the modulation and demodulation processes, and can be easily used to integrate wired, wireless, or optical telecommunication systems; as illustrated in FIG. 1, in traditional systems, a carrier (2) with a carrier frequency (23) is used as the basis of transmission, while the modulating signal (1) may have a modulating frequency (48), no greater than half the carrier frequency (23). The technique that is the basis for our design consists of using the carrier signal in such a way that it is possible to send different pieces of information, one in the positive part of the carrier and the other in the negative part, this technique mixes an analogical treatment of the signal with a digital treatment and, unlike systems like OOK, very few parasitic harmonics are generated, which contributes to the use of a narrow frequency band for the transmissions, in FIG. 2 the basic principle of our system can be appreciated: the information (4) train, consisting of a series of ones and zeros (serial information), to which a synchrony signal (5) has been added, is used to modulate a sine signal that constitutes the carrier, the synchrony signal (5) is included inside the serial information (4) train, so that when demodulating the signal, it is possible to identify the start and end of a certain text, page, or graphics. The modulated signal (3) shows that the carrier is modulated in such a way that within it there is distinguishable information in both the positive and negative parts of the signal, ones and zeros are characterized within this signal, according to amplitude, whether or not some preset levels of amplitude, both positive and negative, are exceeded. Vup will be the minimum magnitude of amplitude that defines a one, and Vun will be relate to the wave negative part, when the lobe or the sinusoidal signal does not exceed these levels, it will be considered a zero, likewise, it is possible to generate a synchrony signal (5), which is characterized by exceeding the Vs level, without exceeding the Vup level; in FIG. 2, the space between the zero level or reference level and the sinusoidal signal has been shaded for clarity, but it will be considered a one in so far as the sinusoidal signal exceeds the Vup level in its positive part or the Vun level in its negative part.

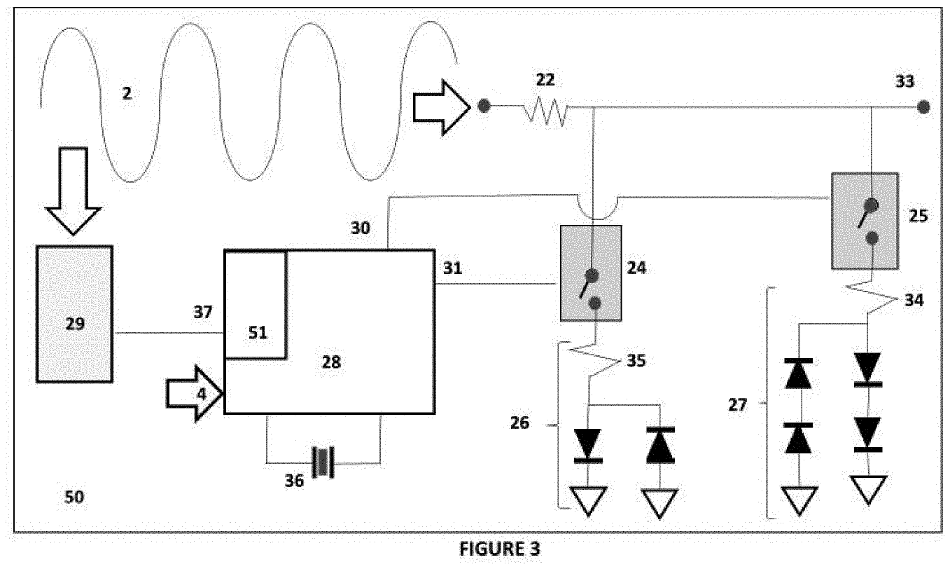

FIG. 3 shows a circuit used to perform this type of modulation, in this diagram, a frequency carrier is processed to produce a signal like the modulated signal (3) in FIG. 2, a zero-crossing detector (29) allows to establish a proper synchrony between the frequency (23) of the carrier (2) and the information (4) serial train, the output of the zero-crossing detector (29) is connected to the phasing input (37) of the modulation microcontroller (28), equipped with a modulation crystal (36), which allows the information (4) frequencies and the carrier frequency (23) to remain always in agreement and in phase as a time reference; the modulation microcontroller (28) also has a zero-control output (30) and a synchrony control output (31), for each half cycle of the carrier, when the carrier is required to represent a ONE, the modulation microcontroller (28) will do nothing until the end of this half period, but when it is required to mark a ZERO in this half cycle, the modulation microcontroller (28) will send a signal to the zero-control output (30), which will cause the zero switch (25) to close, forming a voltage divider with the limiting resistor (22) and the zero attenuator assembly (27), which will determine that, for this half cycle, the sinusoidal signal of the carrier will be attenuated to a level of magnitude lower than Vup or Vun, depending on whether it is a carrier positive or negative half cycle (see FIG. 2); the zero-limiting resistor (34) makes smoother the cut-off of the resulting signal at the modulated output (33) point, without this resistor, the carrier sinusoidal signal would be cut off, forming a plateau of plus or minus two bias voltages in a diode, (0.7 for a silicon diode), thus, by including the zero-limiting resistor (34), the modulated output (33) signal acquires a more rounded shape, that is, with fewer harmonics; when wanting to mark a sync signal (5), the modulating microcontroller (28) sends a signal to the sync control output (31), which momentarily closes the sync switch (24), this procedure is like the one described for the implementation of a ZERO, but in this case the attenuation is higher, producing an output signal with a higher magnitude than the Vs level but lower than the Vs2 level in FIG. 2, ensuring that the synchrony signal can be identified by differentiating it from a ONE or a ZERO, in this case, the proper attenuation is achieved by the action of the synch attenuator assembly (26), which includes the synch-limiting resistor (35), this assembly works similarly to the zero-attenuator assembly (27) but, since it has fewer diodes in series, the attenuation is higher. The switches (24) and (25), as well as the resistor (22) and the assemblies (26) and (27), constitute programmable attenuators that allow attenuating the signal of the carrier (2) in a synchronous and programmable way to perform the modulation.

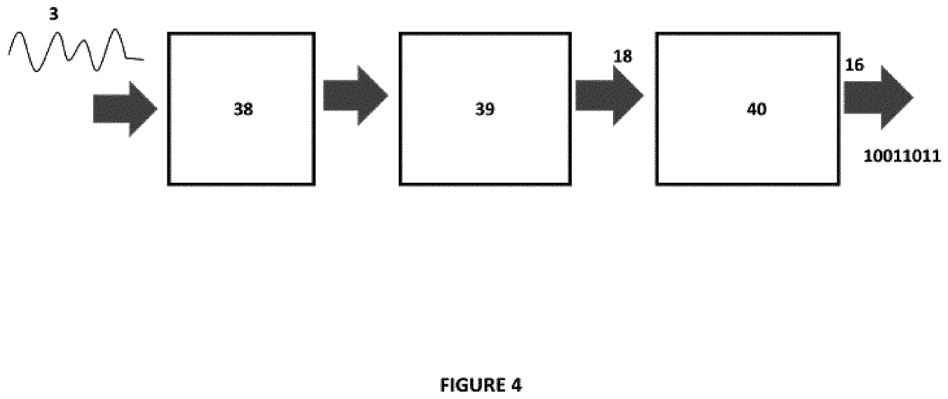

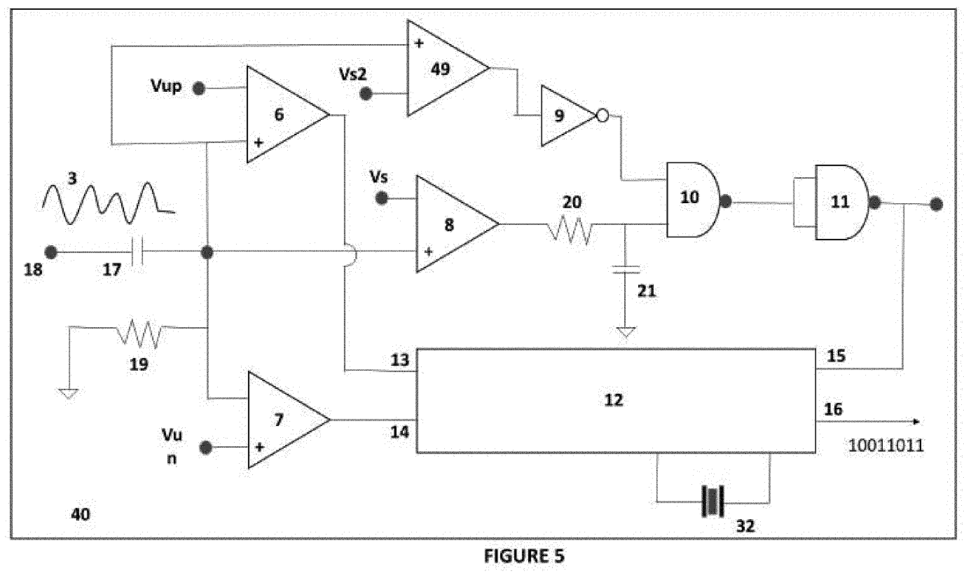

FIG. 4 shows a block diagram of the demodulation circuits, this diagram shows how a modulated signal (3) is introduced to an automatic gain control (38) and then to a zero-centered circuit (39) both circuits are essential for the correct demodulation of the signal, the automatic gain control (38) is a conventional circuit that ensures that the output signal has a predetermined magnitude from peak to peak, while the zero-centering circuit (39) is responsible for centering the signal based on the positive and negative peak values, a simple arrangement of capacitor and resistor cannot perform this task successfully, since the centering that this type of circuit produces is based on the amount of energy or the area from the curve to the reference axis, balancing this magnitude in positive and negative sense, but this does is useless to demodulate the signal according to how it was modulated, the signal input (18) to the demodulator (40) must be perfectly centered with respect to the signal maximum positive value and maximum negative value, so that the circuit of FIG. 5 can be applied to synchronize and demodulate the signal; as shown in the diagram in FIG. 5, the modulated signal (3), which has been previously centered, is applied to the signal input (18) coupled by the input capacitor (17) and the resistor (19) in such a way that this signal is applied to the positive inputs of the positive comparator (6), of the synchrony comparator (8) and of the secondary comparator (49) as well as to the negative input of the negative comparator (7), this set of ultra-high-speed comparators act in such a way that if the signal exceeds the magnitude of the Vup or the Vun level, the corresponding outputs will give this information to the demodulation microcontroller (12) through the one positive input (13) or the one negative input (14), if none of these levels is exceeded neither positively nor negatively, the demodulation microcontroller (12) will determine that the signal corresponding to this half period of the signal is a ZERO, if either of the two levels (Vup or Vun) is exceeded, the signal corresponding to this half period will be a ONE; meanwhile, if the synchrony comparator (8) detects that the signal has exceeded the Vs level (positive), it will determine that the output of the synchrony comparator (8) presents a ONE and the delay capacitor (21) will start to get charged through the delay resistor (20), this delay is necessary to differentiate a synchrony signal from a ONE or a ZERO, since a ONE or a ZERO would exceed the Vs2 level, causing the secondary comparator (49) to present an output of ONE at the input of the inverter (9) whose output will consequently be a ZERO, determining that the output of the NAND gate (10) remains at ONE regardless of the output of the synchrony comparator (8), causing the output of the gate (11) to remain at ZERO, this is the signal of the synchrony input (15) of the demodulation microcontroller (12), indicating that what was received was a ONE or a ZERO and not a synchrony signal, since a ONE will only be registered in the synchrony input (15) when there is a true synchrony signal; a demodulation crystal (32) allows the demodulation microcontroller (12) to verify the synchrony status with the modulated signal (3), as a time reference, which allows the demodulation microcontroller (12) to present the transmitted serial information in its output (16).

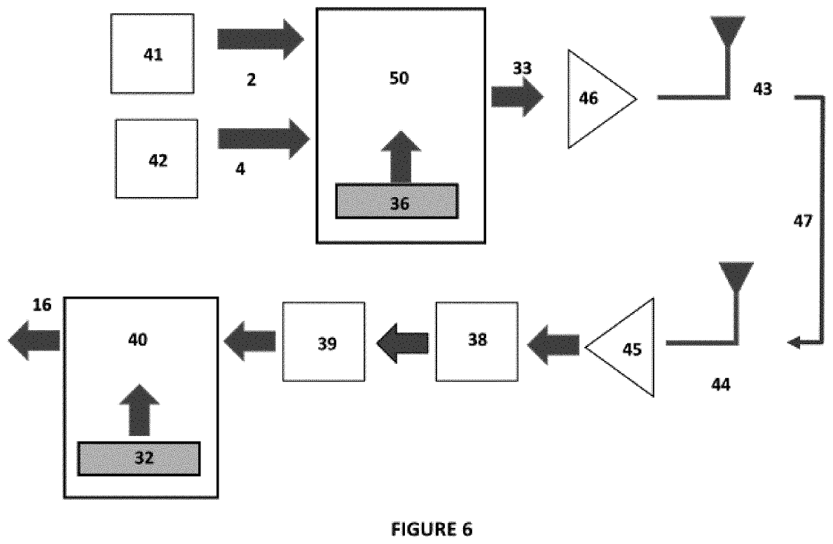

This modulation and demodulation method allows the easy integration of a complete telecommunication system as shown in FIG. 6, where an oscillator (41) and a serial information generator (42) provide a carrier (2) and a digital serial information (4) to a modulator circuit (50) as the one presented in FIG. 3, the modulated output (33) is sent to a power amplifier (46) so that, from there, it can be derived to a transmitting antenna for a wireless transmission (43) or a cable (47) for a wired transmission; reception is achieved through the action of a receiving antenna (44) or a communication cable (47), an input amplifier (45) amplifies the signal to levels suitable for handling, while an automatic gain control (38) is responsible for maintaining the peak-to-peak signal with a minimum variation with respect to a preset magnitude so that the zero-centered circuit (39) can present the signal in the necessary format to the demodulator (40) as shown in FIG. 5, and thus obtain the corresponding output (16).

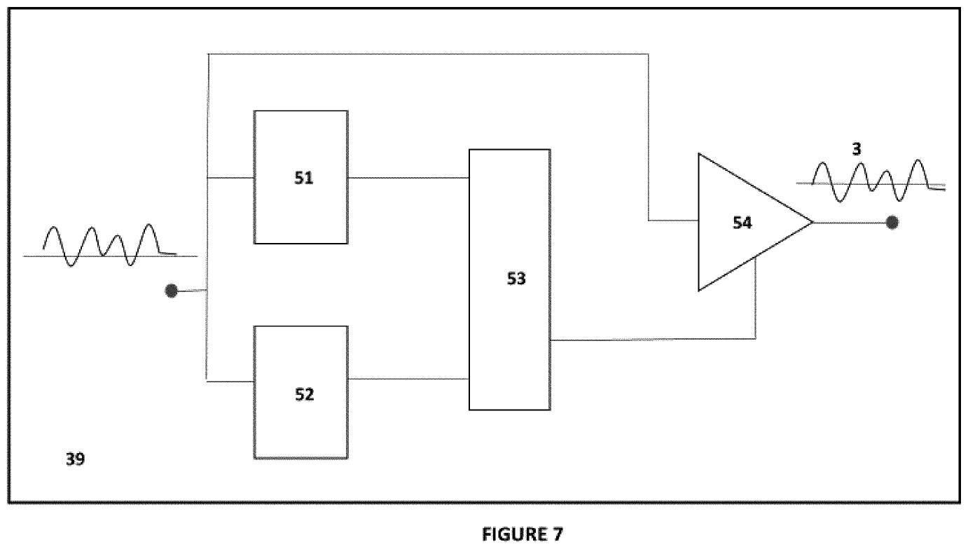

FIG. 7 shows the block diagram of the zero-centered circuit (39) with a positive rectifier (51), a negative rectifier (52) and a zeroing microcontroller (53), which determines the maximum positive and negative values of the input signal and, based on this, manipulates the DC balance of an adjustable level amplifier (54) so that the output of the zero-centered circuit constitutes the input signal to the demodulator, but now perfectly centered with respect to the signal maximum and minimum values.

The essential element for the correct operation of this modulator system, capable of transmitting information at frequencies twice the carrier frequency (four times the maximum indicated by the telecommunications theory), is the synchronization between the information and the carrier, to achieve this, the modulation synchronizer circuit (51), which works closely with the modulation microcontroller (28), as shown in FIG. 3, is essential to avoid the generation of harmonics that corrupt the information.

1. A synchronous modulation system using amplitude modulation characterized by comprising a modulator constituted by a microcontroller (28) connected to a synchronizer (51) which phases and synchronizes the information with respect to the carrier (2) and which also controls a set of programmable attenuators which act in such a way that each bit of information is associated with one half of the carrier signal, either a positive or negative peak, and which also has a time reference crystal and a zero crossing detector (29), as well as a demodulator (40) characterized by having a microcontroller (28), a set of positive and negative level comparators, and a signal zeroing circuit that establishes a reference level located exactly between the maximum positive peak level and the maximum negative peak level of the signal to be demodulated.

2. The synchronous modulation system using amplitude modulation, in accordance with claim 1, wherein the set of programmable attenuators formed by arrays of diodes, resistors and electronic switches (24, 25) controlled by a microcontroller (28) to attenuate every half cycle of the carrier signal to a preset and constant level, so the microcontroller (28) can generate the serial information to be modulated and imprinted on the carrier (2) according to a program and the incoming serial information with the necessary attenuation levels recognizable by a demodulator circuit.

3. (canceled)

4. The synchronous modulation system using amplitude modulation, in accordance with claim 1, wherein the zero-centering circuit (39) is characterized by comprising a positive rectifier (51), and a negative rectifier (52) connected to a microcontroller which, based on the rectified input signal values, varies the balance level of an amplifier, which in turn is connected to the input signal and corrects any imbalance between the maximum positive peak value and the maximum negative peak value of the input signal.

5. A demodulator (40), comprising:
a microcontroller (28);
a set of positive and negative level comparators; and
a signal zeroing circuit, wherein the signal zeroing circuit establishes a reference level located exactly between a maximum positive peak level and a maximum negative peak level of a signal to be demodulated,
wherein the set of positive and negative level comparators connected to preset references and to the signal to be demodulated, so that upon detecting a level in each half cycle of the carrier signal, whether positive or negative, determines whether it is a zero, a one or a synchrony signal, communicating these evaluations directly to the microcontroller (28) by means of inputs provided for this purpose.

6. The demodulator (40), in accordance with claim 5, wherein the zero-centering circuit (39) is characterized by comprising a positive rectifier (51) and a negative rectifier (52) connected to a microcontroller which, based on the rectified input signal values, varies the balance level of an amplifier, which in turn is connected to the input signal and corrects any imbalance between the maximum positive peak value and the maximum negative peak value of the input signal.
